(19) United States
(12) Patent Application Publication
(10) Pub. No.: US 2005/0121809 A1
(43) Pub. Date: Jun. 9, 2005

(54) Information storage apparatus and electronic device in which information storage apparatus is installed

(76) Inventors: Yuichi Yamamoto, Kanagawa (JP); Makoto Motoyoshi, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/432,330

(22) PCT Filed: Oct. 16, 2002
(86) PCT No.: PCT/JP02/10755

(30) Foreign Application Priority Data
Oct. 16, 2001 (JP) 2001-317624

(51) Int. Cl. H01L 23/29

(52) U.S. Cl. 257/791

(57) ABSTRACT

There are disclosed an information storage apparatus and an electronic device mounting the information storage apparatus, wherein when the electronic device mounting an information storage element utilizing a magnetized direction control of a ferromagnetic material, for example a MRAM, receives something strong magnetic field, an erroneous storing of the information is prevented by preventing an influence of the magnetic field to a storage layer. In an information storage apparatus (1) equipped with an information storage element (12) for storing information by utilizing a magneto-resistive effect, a resin material (13) used when the information storage element (12) is mounted is the one being mixed up a high-permeability material, or the information storage element (12) is the one formed with a high-permeability material film or a thin film including a high-permeability material on a part or an entire front surface thereof.

### TECHNICAL FIELD

This invention relates to an information storage apparatus and an electronic device in which the information storage apparatus is mounted, and more particularly to an information storage apparatus equipped with information storage elements for storing information utilizing a magneto-resistive effect and applied a magnetic shield, and to an electronic device in which the information storage apparatus is mounted.

### BACKGROUND TECHNOLOGY

With the rapid spread of a communication device, and particularly a small device for personal use such as a mobile terminal, further high performance such as high integration high speed, low power consumption and the like is required to a memory element and logic element constructing this. Particularly, a non-volatile memory is thought to be absolutely essential for ubiquitous era. Even in the case where a shortage of power source, something trouble, or a server and a network are cut their connections due to failure, such non-volatile memory is able to protect important personal information.

Further, recently, a portable device is so designed as to reduce power consumption as much as possible by carrying out a standby condition to un-necessary circuit block, and if it is possible to realize such non-volatile memory that is able to combine with a work memory and a large sized storage memory, then it becomes possible to reduce the waste of power consumption and memory. Further, so-called [Instant-on] function that is able to activate at once when the power is made on becomes possible if a high speed large sized non-volatile memory is realized.

As a non-volatile memory, a semiconductor flash memory and FRAM (Ferro-electric Random Access Memory) using Ferro-electric substance are known. However, it is difficult to apply a high integration to a flash memory due to its complex configuration, and further it has a defect that the access time is only around 100 ns. On the contrary, it has been pointed out the problem that a FRAM has the possible re-writable number of from 10¹² times to 10¹⁴ times and has a low durability so that it is difficult to completely replace with a static random access memory or a dynamic random access memory. Further, it is also pointed out such problem that a microfabrication of a Ferro-electric capacitor is difficult.

It is a magnetic memory that is so-called MRAM (Magnetic Random Access Memory) having an attention as a non-volatile memory having no such defects, and is described in the article [Wang et al., IEEE Trans. Magn. 33 (1997) p4498], and it also has been keen attention owing to an improvement of characteristics in recent TMR (Tunnel Magneto-resistance) material.

The MRAM is easy to apply a high integration as it has a simple configuration, and it is expected that the number of re-writing number becomes large because it carries out the storage by the rotation of a magnetic moment. Further, an extremely high speed is expected as to access time, and already, the operation with 100 Mhz has been reported in the article [R. Scheuerlein et al, ISSCC Digest of Papers (February 2000) p128-129]. Further it has been greatly improved in the recent year where it becomes possible to get high power due to TMR (Tunnel Magnetic Resistance) effect.

As described above, although the MRAM has advantages in the easiness of high speed and high integration, its writing is carried out with a generated magnetic field by flowing a current through a writing bit line and a writing word line provided near the TMR element. A reverse magnetic field in a storage layer of the TMR element is necessary to be about 20 Oe to 200 Oe, although it depends on material, and the current at this time becomes several mA to several 10 mA. This causes the increase of the consuming current and becomes a large problem when carrying out a low power consumption of a portable device. Accordingly, a development of a material and a configuration that makes the reverse magnetic field lower has been promoted.

In addition, a floating magnetic field in a natural world is several Oe, and by the reduction of the reverse magnetic field, a magnetic noise margin becomes small, and accordingly, this easily invite errors, on the contrary, by the effects of the magnetic noises inside the element and outside the element.

When the MRAM utilizing a magnetized direction control of a ferromagnetic material is installed in a plenty of electronic devices instead of the DRAM in the near future, and when a something strong magnetic field is generated in the vicinity of the MRAM, it is possible to store erroneous data by the rotation of the magnetization in the storage layer due to the strong magnetic field. In order to put into practical use the information storage element utilizing the magnetized direction control of the ferromagnetic material like MRAM, for example, it is necessary to shield the MRAM so as to avoid any effect from the external magnetic field.

### DISCLOSURE OF THE INVENTION

As above described, an information storage apparatus and electronic device mounted with the its information storage apparatus of the present invention is equipped with one of resin including high-permeability material, a high-permeability material film, a thin film including a high-permeability material, a substrate formed with a high-permeability material, and a substrate formed with resin including a high-permeability material, so that it is possible to shield the information storage apparatus from any external magnetic field. Accordingly, it is possible to improve a reliability of the electronic device that includes the information storage apparatus, and the electronic device is able to be put into a practical use.

### BRIEF DESCRIPTION OF THE DRAWINGS

FIG. 1 is a schematic constructive sectional view of a first mode for carrying out an information storage apparatus of the present invention.

FIG. 2 is a schematic constructive sectional view of a second mode for carrying out an information storage apparatus of the present invention.

FIG. 3 is a schematic constructive sectional view of a forth mode for carrying out an information storage apparatus of the present invention.

FIG. 4 is a schematic constructive sectional view of showing another embodiment of the forth mode for carrying out in FIG. 4.

FIGS. 5A and 5B are external views of an electronic device of a mode for carrying out the present invention, and FIG. 5C is a partial sectional view.

FIG. 6 is a partial sectional view showing a mode for carrying out related to an electronic device of the present invention.

### BEST MODE FOR CARRYING OUT THE INVENTION

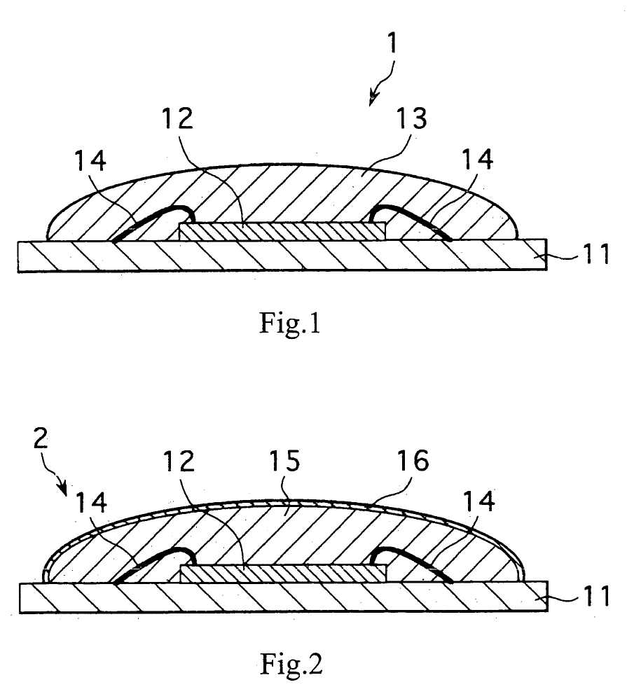

A first mode for carrying out an information storage apparatus of the present invention is explained with reference to a schematic constructive partial sectional view of FIG. 1. In FIG. 1, a MRAM integrated circuit is employed as an information storage element that memorizes information utilizing a magneto-resistive effect, and is depicted a state before mounting in a package.

As shown in FIG. 1, on the substrate 11, there is mounted an information storage element 12. The information storage element 12 is electrically connected with a terminal (not shown in the figure) formed on the substrate 11 and a lead 14. Further on the substrate 11, a resin material 13 covering the information storage element 12 is formed, and the information storage element 12 is sealed by the resin material 13 and the substrate 11.

The above mentioned resin material film 13 is made by dispersing powder of a high-permeability material having a magnetic permeability of 3.5 or more to a polyimide film by 20 wt. % or more, and 95 wt. % or less. When a containing ratio of the above high-permeability material becomes less than 20 wt. %, it becomes difficult to obtain an adequate magnetic shield effect. Further, if the containing ratio of the high-permeability material exceeds 95 wt. %, it becomes difficult to disperse it into the resin. Accordingly, the containing ratio of the high-permeability material relative to the resin is set as mentioned above.

As the high-permeability material, a permalloy, an alphenol of the synthesized magnetic material, a sendust, a high density ferrite of a ferrite material, a single crystal ferrite, a hot-press ferrite, a general sintered ferrite, a magnetic pure iron, a silicon steel, or the like can be used.

Further the above-mentioned resin material 13 may be formed, although not shown in the figure, on an opposite side (back surface side) relative to the side where the information storage element 12 of the substrate 11 is mounted. Or, as shown in the above-mentioned FIG. 1, the resin material 13 may be provided as to cover the information storage element 12, and may also be formed at the back surface side of the substrate 11.

The resin material 13 including the above mentioned high-permeability material is formed by mixing up the power of the high-permeability material into the melted resin within a solvent, and by coating. It is preferable to cure the resin by baking in order to evaporate the solvent in the resin.

Thus configured information storage apparatus 1 not only protects the information storage element 12 by the resin material 13, but also is possible to magnetically shield an upside of the information storage element 12 utilizing the magnetized direction control of the ferromagnetic material. Further, in the configuration where the resin material 13 is provided at the back surface of the substrate 11, it is possible to magnetically shield the substrate 11 side of the information storage element 12.

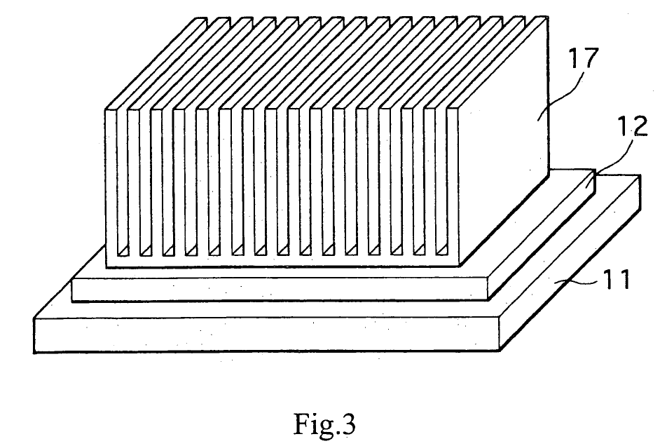

Next, a second mode for carrying out the information storage apparatus according to the present invention is explained with reference to a schematic constructive partial sectional view in FIG. 2. In FIG. 2, a MRAM integrated circuit is used as an information storage element for storing information by utilizing the magneto-resistive effect, and is shown a state before it is installed in a package.

As shown in FIG. 2, on the substrate 11, there is mounted an information storage element 12. The information storage element 12 is electrically connected with a terminal (not shown in the figure) formed on the substrate 11 and a lead 14. Further, on the substrate 11, a protective film 15 covering the information storage element 12 is formed, and the information storage element 12 is sealed by the protective film 15 and the substrate 11.

At a front surface of the protective film 15, a high-permeability material film 16 is formed. A film thickness thereof is set to be the thickness suitable for functioning a magnetic protection (magnetic shield) effect. For example, if the high-permeability material film 16 is formed with a permalloy, the thickness thereof is set to be from 0.1 μm to 1000 μm.

As the high-permeability material, a thin film of an alphenol of the synthesized magnetic material, a sendust, a high density ferrite of a ferrite material, a single crystal ferrite, a hot-press ferrite, a general sintered ferrite, a magnetic pure iron, a silicon steel, or the like may be employed in addition to the permalloy.

Further, a resin film including a high-permeability material may be formed instead of the high-permeability material film 16. The resin film as mentioned above may be made by dispersing a powder of a high-permeability material having a magnetic permeability of 3.5 or more to a polyimide film by the amount of 20 wt. % or more and 95 wt. % or less. When a containing ratio of the above high-permeability material becomes less than 20 wt. %, it becomes difficult to obtain an adequate magnetic shield effect. Further, if the content of the high-permeability material exceeds 95 wt. %, it becomes difficult to disperse it into the resin. Accordingly, the content of the high-permeability material relative to the resin is set as mentioned above.

A powder of a high-permeability material used for the above resin film may be employed the powder similar to that explained before.

The above high-permeability material film 16 may be formed by, for example, a film forming technology based on a PVD (Physical Vapor Deposition) method such as a sputtering, a deposition method or the like. The resin material including the above mentioned high-permeability material is formed by mixing up the powder of the high-permeability material into the melted resin by a solvent, and by coating. It is preferable to cure the resin by baking in order to evaporate the solvent in the resin.

Further the above mentioned high-permeability material film 16 may be formed, although not shown in the figure, on an opposite side (back surface side) relative to the side where the information storage element 12 of the substrate 11 is mounted. Or, as shown in the previous FIG. 2, the high-permeability material film 16 is provided as to cover a front surface of the protective film 15 which covers the information storage element 12, and may be also formed at the back surface side of the substrate 11.

Thus configured information storage apparatus 2 protects the information storage element 12 by the protective film 15, and also is possible to magnetically shield the upside of the information storage element 12 by the high-permeability material film 16 (or the resin film including the high-permeability material). Further in the configuration where the high-permeability material film 16 (or resin film including the high-permeability material) is provided at the back surface of the substrate 11, it is possible to magnetically shield the substrate 11 side of the information storage element 12.

Next, a third mode for carrying out related to the information storage apparatus of the present invention is explained here-in-after.

In the information storage apparatuses 1 and 2 shown in the FIG. 1 and FIG. 2, it is possible to form the substrate 11 with the material in which a high-permeability material is mixed. The resin substrate as mentioned above may be made by dispersing a powder of a high-permeability material having a magnetic permeability of 3.5 or more in an insulating organic resin such as a polystyrol, a bakelite, a polyimide, or the like by the amount of 20 wt. % or more and 95 wt. % or less. When the containing ratio of the above high-permeability material becomes less than 20 wt. %, it becomes difficult to obtain adequate magnetic shield effect. Further, if the content of the high-permeability material exceeds 95 wt. %, it becomes difficult to disperse it into the resin. Accordingly, the content of the high-permeability material relative to the resin is set as mentioned above.

The above substrate 11 is formed by mixing up the powder of a high-permeability material in the resin dissolved by a solvent, forming, and curing.

As the above-mentioned high-permeability material, a high-permeability material similar to the one explained in the above is possible to be employed.

In the information storage apparatus configured as above, it is possible to magnetically shield the substrate 11 side of the information storage element 12 by constructing the substrate 11 with the one including the high-permeability material.

Next, a forth mode for carrying out related to the information storage apparatus of the present invention is explained with reference to a schematic constructive partial sectional view in FIG. 3, here-in-after. FIG. 3 shows MRAM integrated circuit is employed as an information storage element for storing information by utilizing the magneto-resistive effect in a state before installed in a package.

As shown in FIG. 3, the information storage apparatus 12 is mounted on the substrate 11 made of a BGA (Ball Grid Array) substrate. A radiator (heat sink) 17 is mounted on the information storage apparatus 12, and has a function of radiating heat of the information storage element 12.

The above mentioned radiator (heat sink) 17 may be formed by including a high-permeability material. For example, the radiator 17 is formed by a permalloy. Or, the above mentioned radiator 17 may be formed by the one including a high-permeability material.

Or, the radiator 17 is to be the one made by forming a high-permeability material film on its front surface. For example, in the radiator 17, a main body thereof is made of an aluminum or a copper having a high heat conductance, and the one where the front surface thereof is coated by the high-permeability material film. Or, the radiator 17 is to be the one formed of a thin film including a high-permeability material. For example, as a thin film including such high-permeability material, there is a resin film in which a powder of a high-permeability material is mixed up as explained before. As the above-mentioned high-permeability material, a material similar to the one explained as above is able to be employed.

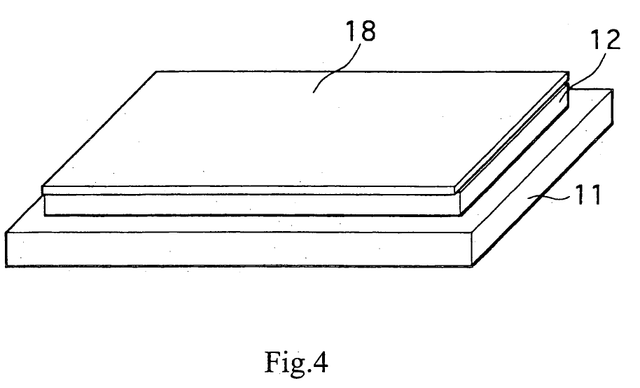

Next, another embodiment related to the forth mode for carrying out is explained with FIG. 4.

As shown in FIG. 4, the information storage element 12 is mounted on the substrate 11 made of a BGA (Ball Grid Array) substrate. A radiator (heat spreader) 18 is formed on the information storage element 12, and has a function of radiating a heat of the information storage element 12.

The radiator (heat spreader) 18 is made of a high-permeability material. For example, the radiator 18 is formed with a permalloy. Or, the radiator 18 is made of the one including a high-permeability material on its front surface.

Or, the radiator 18 is to be the one made by forming a high-permeability material film on its front surface. For example, in the radiator 18, a main body thereof is made of an aluminum or a copper having a high heat conductance, and the one where the front surface thereof is coated by the high-permeability material film. Or, the radiator 18 is to be the one formed of a thin film including a high-permeability material. For example, as a thin film including such high-permeability material, there is a resin film in which a powder of a high-permeability material is mixed up as explained before. As the above-mentioned high-permeability material, a material similar to the one explained as above is able to be employed.

In the information storage apparatus 3 configured as above, it is possible to magnetically shield an upside of the information storage element 12 with the radiator 17 (or 18).

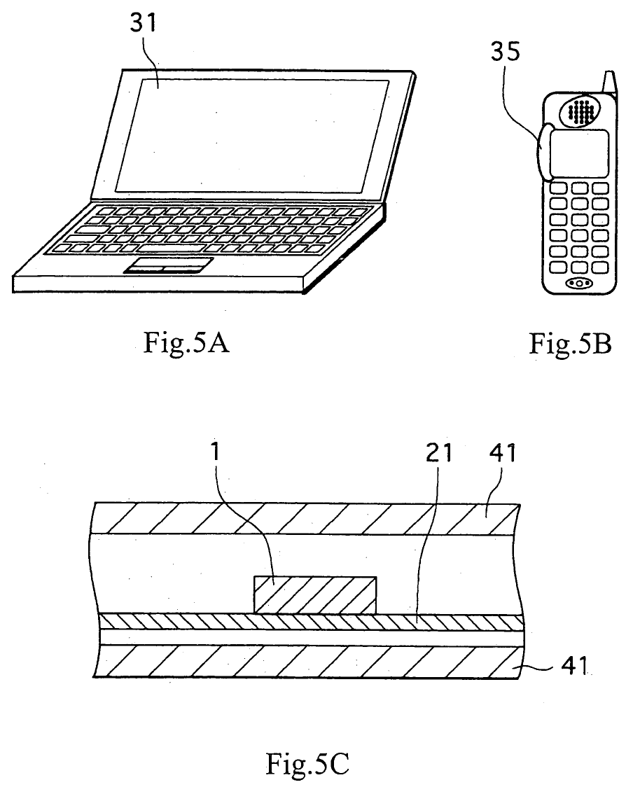

One example of an electronic device mounting an information storage apparatus having an information storage element for storing information by utilizing the magneto-resistive effect is explained. FIG. 5A shows an external view of a notebook type personal computer, and FIG. 5B shows an external view of a mobile phone. In addition, FIG. 5C shows a partial sectional construction of the housing of the partial sectional construction, and a printed circuit board installed in the housing and mounting the information storage apparatus.

In an electronic device such as a notebook type personal computer 31, a mobile phone 35 or the like as shown in above-mentioned FIG. 5A and FIG. 5B, a printed circuit board 21 mounting the information storage apparatus 1 for storing information by utilizing the magneto-resistive effect is protected by the housing 41. The above-mentioned housing 41 is itself formed with a high-permeability material.

As the high-permeability material to be used in the above-mentioned housing 41, a permalloy, an alphenol of the synthesized magnetic material, a sendust, a high density ferrite of a ferrite material, a single crystal ferrite, a hot-press ferrite, a general sintered ferrite, a magnetic pure iron, a silicon steel, or the like may be employed.

Or, the above mentioned housing 41 is to be the one including at least a high-permeability material. For example, it is made of a resin including a powder of the high-permeability material. The resin as mentioned above may be made by dispersing a powder of a high-permeability material having a magnetic permeability of 3.5 or more in a resin such as an ABS resin, an AS resin, a PBT resin, a polyimide resin, a polyamide resin, an epoxy resin, a methacryl resin, or the like by the amount of 20 wt. % or more and 95 wt. % or less. When a containing ratio of the above high-permeability material becomes less than 20 wt. %, it becomes difficult to obtain an adequate magnetic shield effect. Further, if the content of the high-permeability material exceeds 90 wt. %, it becomes impossible to maintain the strength of the resin. Accordingly, the content of the high-permeability material relative to the resin is set as mentioned above.

As the powder of the high-permeability material to be used in the above-mentioned housing 41, a powder of a permalloy, an alphenol of the synthesized magnetic material, a sendust, high density ferrite of a ferrite material, a single crystal ferrite, a hot-press ferrite, a general sintered ferrite, a magnetic pure iron, a silicon steel, or the like may be employed.

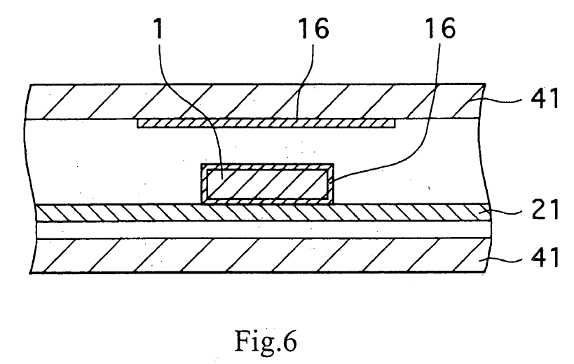

As shown in a partial sectional view in FIG. 6, inside of the housing 41, there is installed the printed circuit board 21 on which an electronic part such as the information storage apparatus 1 for storing information by utilizing the magneto-resistive effect is mounted, for example. A high-permeability material film (or a thin film containing a high-permeability material) may be formed on a periphery of this information storage apparatus 1. Further, the high-permeability material film (or a thin film containing a high-permeability material) may be formed above inner surface of the housing 41 of the information storage apparatus 1.

In the electronic device as above configured, a high-permeability material film (or a thin film containing a high-permeability material) is formed on either outer surface or inner surface of the housing 41, so that it is possible to magnetically shield the information storage apparatus 1. Further, a high-permeability material film (or a thin film containing a high-permeability material) is formed on a periphery of the information storage apparatus 1, so that it is possible to magnetically shield the information storage apparatus 1.

It is possible to simultaneously carry out several ways of the magnetic shield explained in each mode of carrying out in the above. By carrying out plural ways of the magnetic shield, it is possible to carry out the magnetic shield more effectively.

In the above-described each mode for carrying out, an electronic device mounting an information storage apparatus for storing information utilizing a magneto-resistive effect is explained, and also by applying a thin film including a high-permeability material film or a high-permeability material to an electronic device to which a DRAM is mounted, it is possible to obtain such magnetic shield effect, for example.

The resin including the high-permeability material, the high-permeability material film, the thin film including the high-permeability material, or the like are formed as described below.

For example, when a part material surrounding the information storage element is a resin based material, the above mentioned part material is formed by mixing up a powder of a high-permeability material (permalloy, for example) into a liquid or a liquid conditioned resin, and by forming it.

If the part material surrounding the information storage element is a ceramic based material, the above mentioned part material is formed by mixing up a powder of a high-permeability material (permalloy, for example) into a ceramic powder material, and by sintering them.

Along a front surface of the part material surrounding the information storage element, the high-permeability material is possible to be formed to be a thin film form by a film forming technology such as a sputtering, a deposition method, or the like. Or, it may be a method for spray-coating a powder of a high-permeability material.

The above-mentioned various forming methods are possible to be applied to all of the above-explained high-permeability materials.

There are many types of high-permeability material for shielding the information storage element as mentioned above. A magnetic shield effect is proportional to a magnetic permeability of these high-permeability materials. Therefore, when the external magnetic field is small and the magnetic saturation of the material is not a matter of problem, a larger magnetic shield effect is obtained by using a high-permeability material. On the contrary, when the external magnetic field is large, the reduction of a magnetic permeability is concerned, so that it is effective to use a material having a high saturation flux density among high-permeability materials, for example, the material such as a magnetic pure iron, a silicon steel, or the like.

### APLICABILITY IN THE INDUSTRY

The present invention is an information storage apparatus and an electronic device mounting the information storage apparatus being carried out in order to solve the above-mentioned problems.

In the above-mentioned information storage apparatus, the information storage element is magnetically shielded from an external magnetic field by utilizing a resin including a high-permeability material or a thin film including a high-permeability material so that the improvement in the reliability of the information storage apparatus is expected.

In the information storage apparatus, the information storage element is magnetically shielded from an external magnetic field by utilizing a substrate including a high-permeability material, or a substrate being formed thereon a high-permeability material film or a thin film including a high-permeability material, so that the improvement in the reliability of the information storage apparatus is expected.

In the above mentioned information storage apparatus, the information storage element is magnetically shielded from an external magnetic field by utilizing a radiator including a high-permeability material, or the one on which a high-permeability material film is formed or a thin film including a high-permeability material is used at front surface, so that the improvement in the reliability of the information storage apparatus is expected.

In the electronic device mounting the above mentioned information storage apparatus, the information storage element is magnetically shielded from an external magnetic field by using the housing of the electronic device including a high-permeability material, or the housing which is formed with a high-permeability material film or a thin film including a high-permeability material on at least a part or entire surface of front and or back surface thereof, so that the improvement in the reliability of the electronic device is expected.

1. An information storage apparatus including an information storage element for storing information by utilizing a magneto-resistive effect, said information storage apparatus is characterized in which:
a resin material used when said information storage element is mounted includes a high-permeability material.

2. The information storage apparatus as cited in claim 1, characterized in which:
said resin material is formed at least a part or entire surface of said information storage element.

3. An information storage apparatus including an information storage element for storing information by utilizing a magneto-resistive effect, said information storage apparatus is characterized in which:
said information storage element is formed with a high-permeability material film, or a thin film including a high-permeability material on a part or an entire surface of a front surface thereof.

4. The information storage apparatus as cited in claim 3, characterized in which:
said thin film including the high-permeability material includes a resin film including a high-permeability material.

5. An information storage apparatus including an information storage element for storing information by utilizing a magneto-resistive effect, said information storage apparatus is characterized in which:
a substrate on which said information storage element is mounted is formed by mixing up a high-permeability material.

6. An information storage apparatus including an information storage element for storing information by utilizing a magneto-resistive effect, said information storage apparatus is characterized in which:
a substrate on which said information storage element is mounted is formed with a high-permeability material film or a thin film including a high-permeability material on a part or an entire surface of a front surface thereof.

7. The information storage apparatus as cited in claim 6, characterized in which:
said thin film including the high-permeability material includes a resin film including a high-permeability material.

8. An information storage apparatus including an information storage element for storing information by utilizing a magneto-resistive effect, said information storage apparatus is characterized in which:
a radiator of said information storage apparatus includes at least a high-permeability material.

9. The information storage apparatus as cited in claim 6, characterized in which:
a part or all of said radiator is formed with a high-permeability material.

10. An information storage apparatus including an information storage element for storing information by utilizing a magneto-resistive effect, said information storage apparatus is characterized in which:
a radiator of said information storage apparatus includes at least a high-permeability material.

11. The information storage apparatus as cited in claim 10, characterized in which:
said thin film including said high-permeability material is made of a resin film including a high-permeability material.

12. An electronic device mounting an information storage apparatus which is equipped with an information storage element for storing information utilizing a magneto-resistive effect; said electronic device is characterized in which:
a housing of said electronic device is at least made of the one including a high-permeability material.

13. An electronic device mounting an information storage apparatus equipped with an information storage element for storing information by utilizing magneto-resistive effect, said electronic device mounting an information storage apparatus is characterized in which
a housing of said electronic device is formed with a high-permeability material film or a thin film including a high-permeability material at least a part or entire surface of a front surface and a back surface thereof.

14. The electronic device mounting the information storage apparatus as cited in claim 13, characterized in which:
said thin film including said high-permeability material is made of a resin film including a high-permeability material.
